(19) United States
(12) Patent Application Publication
(10) Pub. No.: US 2015/0138869 A1
(43) Pub. Date: May 21, 2015

(54) NON-VOLATILE MEMORY

(71) Applicant: FARADAY TECHNOLOGY CORPORATION, Hsinchu (TW)

(72) Inventors: Chih-Kang Chiu, Hsinchu County (TW); Wei-Chang Wang, Kaohsiung City (TW); Sheng-Tai Young, Hsinchu County (TW)

(73) Assignee: FARADAY TECHNOLOGY CORPORATION, Hsinchu (TW)

(21) Appl. No.: 14/180,703

(22) Filed: Feb. 14, 2014

(30) Foreign Application Priority Data
Nov. 18, 2013 (TW) 102141932

(51) Int. Cl. G11C 17/12

(52) U.S. Cl. CPC G11C 17/123
USPC 365/104

(57) ABSTRACT

A non-volatile memory includes a memory unit. The memory unit includes a first word line, a second word line, a control line, a logic circuit, a bit line, a first cell, and a second cell. The logic circuit has a first input terminal connected to the first word line, a second input terminal connected to the second word line, and an output terminal connected to the control line. The first cell has a control terminal connected to the first word line, a first terminal connected to the control line, and a second terminal selectively connected to the bit line. The second cell has a control terminal connected to the second word line, a first terminal connected to the control line, and a second terminal selectively connected to the bit line.

This application claims the benefit of Taiwan Patent Application No. 102141932, filed Nov. 18, 2013, the subject matter of which is incorporated herein by reference.

### FIELD OF THE INVENTION

The present invention relates to a non-volatile memory, and more particularly to a non-volatile memory with reduced sub-threshold leakage current.

### BACKGROUND OF THE INVENTION

As is well known, a non-volatile memory is able to continuously retain data after the supplied power is interrupted. Generally, after the non-volatile memory leaves the factory, the user may program the non-volatile memory in order to record data into the non-volatile memory. According to the number of times the non-volatile memory is programmed, the non-volatile memory may be classified into a multi-time programming memory (also referred as a MTP memory) and a one time programming memory (also referred as an OTP memory). Basically, the stored data of the MTP memory may be modified many times. On the contrary, the OTP memory may be programmed once. After the OTP memory is programmed, the stored data fails to be modified.

A mask read-only memory (also referred as Mask ROM) is another type of non-volatile memory. After the mask read-only memory leaves the factory, all stored data have been recorded therein. The user is only able to read the stored data from the mask read-only memory, but is unable to program the mask read-only memory. That is, before the mask read-only memory is produced, the user has to provide the stored data to the manufacturer of the mask read-only memory. After the mask read-only memory is produced, all stored data have been recorded in the mask read-only memory and cannot be modified.

Since the mask read-only memory has many benefits such as low cost, high reliability and large capacity, the mask read-only memory is widely used in a variety of electronic products.

FIG. 1A is a schematic circuit block diagram illustrating a conventional mask read-only memory. As shown in FIG. 1A, the mask read-only memory 100 comprises word lines WL1˜WLn, bit lines BL1˜BL4, and (n×4) cells S1,1˜Sn,4. Each cell comprises a transistor. For example, the four cells Sn,1˜Sn,4 are defined by the n-th world line WLn and the four bit lines BL1˜BL4 collaboratively. The gate terminals of the four transistors are connected to the n-th world line WLn. The source terminals of the four transistors are connected to a ground terminal G. The drain terminals of the four transistors are selectively connected to the corresponding bit lines.

During the process of fabricating the conventional mask read-only memory 100, the drain terminals of the transistors may be selectively connected to the corresponding bit lines through vias (not shown). At the same time, the storing states of these cells are defined. In case that the drain terminal of the transistor is connected to the corresponding bit line, the cell is in a first storing state (e.g. state “0”). Whereas, in case that the drain terminal of the transistor is not connected to the corresponding bit line, the cell is in a second storing state (e.g. state “1”).

In FIG. 1A, the black solid square node indicates that the drain terminal of the transistor is connected to the corresponding bit line, and the white hollow square node indicates that drain terminal of the transistor is not connected to the corresponding bit line. Consequently, the cell Sn,1 has the second storing state (e.g. state “1”); the cell Sn,2 has the first storing state (e.g. state “0”); and the rest may be deduced by analogy.

FIG. 1B is a schematic timing diagram illustrating associated signals of the mask read-only memory during the read cycle. The x-th word line WLx is a selected word line, and the other word lines WL_other are non-selected word lines. At the time point t0 of the read cycle, all bit lines BL should be pre-charged to a high voltage level Hi. At the time point t1, the bit lines BL have the high voltage level. Consequently, the high voltage level Hi is provided to the x-th word line WLx, and the low voltage level Lo is provided the other word lines WL_other. At the time point t2, the voltages of all bit lines BL are sampled. According to the voltages of all bit lines BL, the storing states of the corresponding cells are realized.

Generally, the voltage of the high voltage level Hi is a core voltage (e.g. 1 V), and the voltage of the low voltage level Lo is the ground voltage of the ground terminal G. Hereinafter, a process of reading data from the mask read-only memory 100 will be illustrated by using the n-th word line WLn as the selected word line.

Firstly, at the time point t0, all bit lines BL1˜BL4 are pre-charged to the high voltage level Hi. At the time t1, the high voltage level Hi is provided to the n-th word line WLn, and the low voltage level Lo is provided to the other word lines (i.e. from the first word line WL1 to the (n−1)-th word line WLn−1).

Since the word lines from WL1 to WLn−1 are all in the low-level state, the cells S1,1˜Sn−1,4 corresponding to the word lines from WL1 to WLn−1 are all disabled.

Moreover, since the n-th word line WLn has the high voltage level Hi and the drain terminal of the transistor of the cell Sn,2 is connected to the second bit line BL2, a driving current is generated by the transistor of the cell Sn,2 and the voltage of the second bit line BL2 is pulled down from the high voltage level Hi to the low voltage level Lo (see the dotted line BL as shown in FIG. 1B). After the time point t1, the voltage of the second bit line BL2 is gradually decreased to the low voltage level Lo.

Moreover, since the n-th word line WLn has the high voltage level Hi and the drain terminals of the transistors of the cells Sn,1, Sn,3 and Sn,4 are not respectively connected to the first bit line BL1, the third bit line BL3 and the fourth bit line BL4, the transistors of the cells Sn,1, Sn,3 and Sn,4 do not generate the driving current. Consequently, the voltages of the first bit line BL1, the third bit line BL3 and the fourth bit line BL4 are not pulled down (see the solid line BL as shown in FIG. 1B). After the time point t1, the voltages of the first bit line BL1, the third bit line BL3 and the fourth bit line BL4 are maintained at the high voltage level Hi.

At the time point t2, the voltages of the bit lines BL1˜BL4 are sampled. That is, the voltages of the bit lines BL1˜BL4 are the high voltage level Hi, the low voltage level Lo, the high voltage level Hi and the high voltage level Hi, respectively. According to the voltages of the bit lines BL1-BL4, the storing states of the cells Sn,1, Sn,2, Sn,3 and Sn,4 are the states “1”, “0”, “1” and “1”, respectively.

Similarly, if the (n−1)-th word line WLn−1 is the selected word line, the storing states of the cells Sn−1,1, Sn−1,2, Sn−1,3 and Sn−1,4 are the states “0”, “1”, “1” and “0”, respectively. The ways of realizing the storing states of the other cells of the mask read-only memory 100 are similar to those mentioned above, and are not redundantly described herein.

However, in the conventional mask read-only memory 100, the sub-threshold leakage current of the cell may result in erroneous judgment of the storing state. The reason will be illustrated as follows.

FIG. 2A is a schematic circuit block diagram illustrating a portion of the conventional mask read-only memory of FIG. 1A. In FIG. 2A, only the first bit line BL1 and the word lines WL1˜WLn of the mask read-only memory are shown. The drain terminal of the transistor of the cell Sn,1 is not connected to the first bit line BL1, but the drain terminals of the transistors of the cells S1,1˜Sn−1,1 are all connected to the first bit line BL1. Consequently, the storing state of the cell Sn,1 is the state “1”, and the storing states of the cells S1,1˜Sn−1,1 are “0”.

If the n-th word line WLn is the selected word line during the read cycle, the n-th word line WLn has the high voltage level Hi. Theoretically, the voltage of the first bit line BL1 is maintained at the high voltage level Hi.

Moreover, if the n-th word line WLn is the selected word line, the cells S1,1˜Sn−1,1 are disabled. However, since the drain terminals of the transistors of the cells S1,1˜Sn−1,1 are all connected to the first bit line BL1, a difference between the drain terminal and the source terminal of the transistor of each of the cells S1,1˜Sn−1,1 may generate a sub-threshold leakage current I_{L}.

Please refer to FIG. 2A. A total of (n−1) cells S1,1˜Sn−1,1 may generate the sub-threshold leakage current I_{L}. The magnitude of the total leakage current is equal to (n−1)×I_{L}. In other words, if the number of the word lines WL is too large, the magnitude of the total leakage current is very large. Under this circumstance, the voltage of the first bit line BL1 is pulled down from the high voltage level Hi to the low voltage level Lo. In other words, the state “1” of the cell Sn,1 is erroneously judged as the state “0”.

FIG. 2B is a schematic timing diagram illustrating associated signals of first bit line BL1 and the word lines WL1˜WLn of the mask read-only memory during the read cycle. At the time point t0, the first bit line BL1 is pre-charged to the high voltage level Hi. At the time t1, the high voltage level Hi is provided to the n-th word line WLn, and the low voltage level Lo is provided to the word lines from WL1 to WLn−1.

Since the magnitude of the total leakage current of the cells S1,1˜Sn−1,1 is very large, the voltage of the first bit line BL1 is gradually decreased to the low voltage level Lo after the time point t1. At the time point t2, the voltage of the first bit line BL1 is sampled. According to the voltages of all bit lines BL, the storing states of the corresponding cells are realized. Consequently, the storing state of the cell Sn,1 is erroneously judged as the state “0”.

As known, it is difficult to effectively reduce the sum of the sub-threshold leakage currents I_{L} (i.e. the total leakage current). For avoiding erroneous judgment which is caused by the sub-threshold leakage currents I_{L} of the cells, it is necessary to limit the number of the word lines WL. For example, the upper limit of the number of the word lines WL for each bit line BL is 128. If the number of the word lines WL for each bit line BL exceeds 128, the storing state of the cell may be erroneously judged.

### SUMMARY OF THE INVENTION

The present invention provides a non-volatile memory. The non-volatile memory comprises a logic circuit and a control line. The logic circuit has simple circuitry. The control line is used as a shared source line. By using the logic circuit to adjust the voltage of the control line, the sub-threshold leakage current of the cell can be suppressed.

An embodiment of the present invention provides a non-volatile memory. The non-volatile memory includes a first memory unit. The first memory unit includes a first word line, a second word line, a first control line, a first logic circuit, a first bit line, a first cell, and a second cell. The first logic circuit has a first input terminal connected to the first word line, a second input terminal connected to the second word line, and an output terminal connected to the first control line. If one of the first word line and the second word line is a selected word line, the output terminal of the first logic circuit provides a first voltage level to the first control line. If the first word line and the second word line are non-selected word lines, the output terminal of the first logic circuit provides a second voltage level to the first control line. The first cell has a control terminal connected to the first word line, a first terminal connected to the first control line, and a second terminal selectively connected to the first bit line. The second cell has a control terminal connected to the second word line, a first terminal connected to the first control line, and a second terminal selectively connected to the first bit line.

Another embodiment of the present invention provides a non-volatile memory. The non-volatile memory includes a bit line, M word lines, a control line, a logic circuit, and M cells. M is a positive integer larger than 2. The logic circuit has M input terminals connected to the M word lines, and has an output terminal connected to the control line. If one of the M word lines is a selected word line, the output terminal of the logic circuit provides a first voltage level to the control line. Whereas, if the M word lines are non-selected word lines, the output terminal of the logic circuit provides a second voltage level to the control line. Each of the M cells has a control terminal connected to one of the M word lines, a first terminal connected to the control line, and a second terminal selectively connected to the bit line.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic circuit block diagram illustrating a conventional mask read-only memory;

FIG. 1B (prior art) is a schematic timing diagram illustrating associated signals of the mask read-only memory during the read cycle;

FIG. 2A (prior art) is a schematic circuit block diagram illustrating a portion of the conventional mask read-only memory of FIG. 1A;

FIG. 2B (prior art) is a schematic timing diagram illustrating associated signals of first bit line BL and the word lines WL1˜WLn of the mask read-only memory during the read cycle;

FIG. 3 is a schematic circuit block diagram illustrating a non-volatile memory according to a first embodiment of the present invention;

FIG. 4 is a schematic circuit block diagram illustrating a non-volatile memory according to a second embodiment of the present invention;

FIG. 5 is a schematic circuit block diagram illustrating a portion of a non-volatile memory according to a third embodiment of the present invention; and

FIG. 6 is a schematic circuit block diagram illustrating a portion of a non-volatile memory according to a fourth embodiment of the present invention.

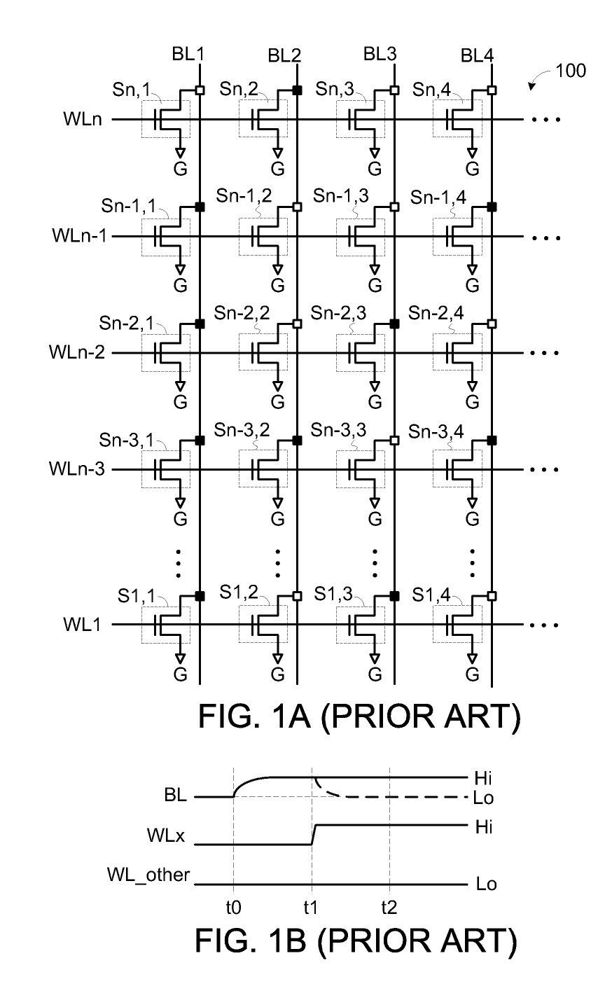

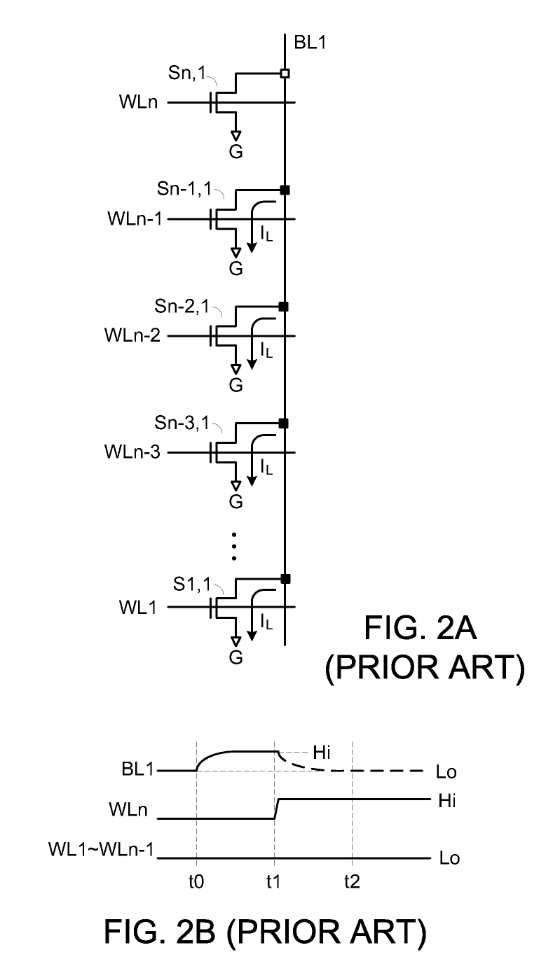

### DETAILED DESCRIPTION OF PREFERRED EMBODIMENTS

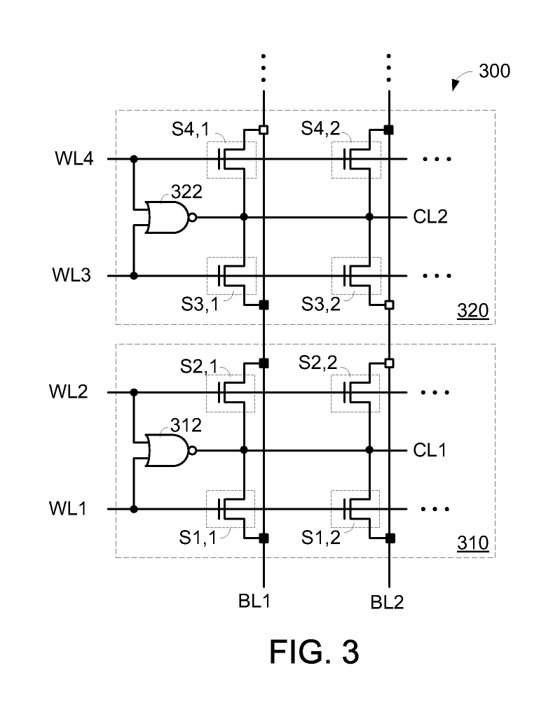

FIG. 3 is a schematic circuit block diagram illustrating a non-volatile memory according to a first embodiment of the present invention. The non-volatile memory is illustrated by using a mask read-only memory 300 as an example. It is noted that the configuration of FIG. 3 may be applied to other types of non-volatile memories.

As shown in FIG. 3, the mask read-only memory 300 comprises plural memory units. For clarification and brevity, only two memory units 310 and 320 are shown in the drawing. In an embodiment, each memory unit is defined by two word lines WL and plural bit lines BL. As the number of bit lines BL increases, the number of cells increases. Alternatively, each memory may be defined by two word lines WL and a single bit line BL. As the number of the word lines WL increases, the number of the memory units increases.

The first memory unit 310 comprises a first logic circuit 312, a first control line CL1, a first word line WL1, a second word line WL2, a first bit line BL1, a second bit line BL2, and four cells S1,1˜S2,2 corresponding to these bit lines and these word lines. Moreover, each of the cells S1,1˜S2,2 comprises a transistor.

The first logic circuit 312 of the first memory unit 310 is a NOR gate. Two input terminals of the first logic circuit 312 are connected to the first word line WL1 and the second word line WL2, respectively. An output terminal of the first logic circuit 312 is connected to the first control line CL1.

The first word line WL1 corresponds to the two cells S1,1˜S1,2. The gate terminal of the transistor of each of the cells S1,1˜S1,2 is connected to the first word line WL1. The source terminal of the transistor is connected to the first control line CL1. The drain terminal of the transistor is selectively connected to the corresponding bit line.

The second word line WL2 corresponds to the two cells S2,1˜S2,2. The gate terminal of each of the cells S2,1˜S2,2 is connected to the second word line WL2. The source terminal of the transistor is connected to the first control line CL1. The drain terminal of the transistor is selectively connected to the corresponding bit line. Obviously, the first control line CL1 is used as a shared source line of the first memory unit 310 and connected to the source terminals of all transistors of the first memory unit 310.

In FIG. 3, the black solid square node indicates that the drain terminal of the transistor is connected to the corresponding bit line, and the white hollow square node indicates that drain terminal of the transistor is not connected to the corresponding bit line. Consequently, in the cells S1,1˜S2,2, if the drain terminal of the transistor is connected to the corresponding bit line, the cell has a first storing state (e.g. the state “0”). Whereas, if the drain terminal of the transistor is not connected to the corresponding bit line, the cell has a second storing state (e.g. the state “1”).

The circuitry of the second memory unit 320 is similar to the circuitry of the first memory unit 310, and is not redundantly described herein. The operations of the mask read-only memory 300 will be illustrated in more details as follows.

In the configuration of the mask read-only memory 300, the source terminals of the transistors of all cells are not all directly connected to the ground terminal, but the source terminals of the transistors of all cells are connected to the corresponding control lines. That is, the source terminals of the transistors of the cells S1,1˜S2,2 are all connected to the first control line CL1; the source terminals of the transistors of the cells S3,1˜S4,2 are all connected to the second control line CL2; and the rest may be deduced by analogy.

Moreover, the memory units 310 and 320 have respective logic circuits 312 and 322. The input terminals of the logic circuits 312 and 322 are connected to corresponding word lines. The output terminals of the logic circuits 312 and 322 are connected to the control lines CL1 and CL2, respectively.

During a read cycle of the mask read-only memory 300, only one word line is the selected word line, and the other word lines are the non-selected word lines. According to the properties, the logic circuits 310 and 320 are designed to reduce the sub-threshold leakage currents of the cells. Hereinafter, the operations of the mask read-only memory 300 will be illustrated by using the fourth word line WL4 as the selected word line.

After the bit lines BL1˜BL2 are pre-charged to a high voltage level Hi, the high voltage level Hi is provided to the fourth word line WL4, and a low voltage level Lo is provided to the other word lines (i.e. the first word line WL1 to the third word line WL3). Consequently, the first logic circuit 312 provides the high voltage level Hi to the first control line CL1, and the second logic circuit provides the low voltage level Lo to the second control line CL2.

In the second memory unit 320, the fourth word line WL4 has the high voltage level Hi, and the drain terminal of the transistor of the cell S4,1 is not connected to the first bit line BL1. Consequently, the cell S4,1 does not generate the driving current, and the first bit line BL1 is maintained at the high voltage level Hi. Moreover, since the fourth word line WL4 has the high voltage level Hi and the drain terminal of the transistor of the cell S4,2 is connected to the second bit line BL2, the voltage of the second bit line BL2 is pulled down to the low voltage level Lo. Consequently, after the voltages of the bit lines BL1˜BL2 are sampled, the storing states of the cells S4,1 and S4,2 are the state “1” and the state “0”, respectively.

In the first memory unit 310, both of the first bit line BL1 and the first control line CL1 have the high voltage level Hi. Consequently, there is no voltage difference between the drain terminal and the source terminal of the transistor of the cell S1,1, and there is no voltage difference between the drain terminal and the source terminal of the transistor of the cell S2,1. Consequently, the cells S1,1 and S2,1 do not generate the sub-threshold leakage current. Under this circumstance, the first bit line BL1 is maintained at the high voltage level Hi and not influenced by the sub-threshold leakage current.

By the mask read-only memory 300 of the first embodiment, even if the number of the word lines WL can be increased to 256 or more, the storing state of each cell can be accurately judged. In other words, the erroneous judgment is avoided.

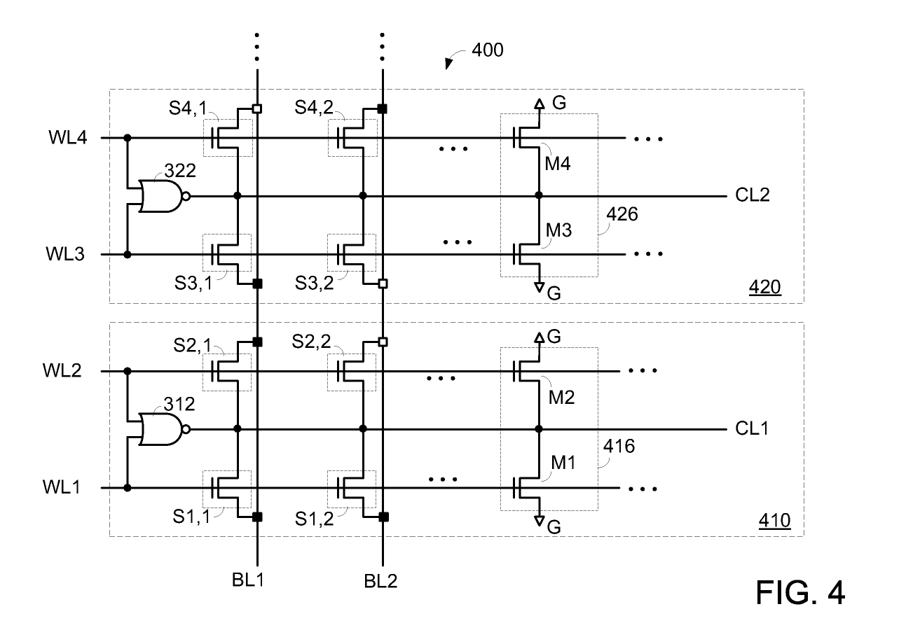

FIG. 4 is a schematic circuit block diagram illustrating a non-volatile memory according to a second embodiment of the present invention. In comparison with the first embodiment, the mask read-only memory 400 of this embodiment further comprises a first footer circuit 416 and a second footer circuit 426. The first footer circuit 416 is included in the first memory unit 410, and a second footer circuit 426 is included in the second memory unit 420. Hereinafter, the configurations and the operating principles of the first footer circuit 416 and the second footer circuit 426 will be illustrated. The other parts of the mask read-only memory 400 of this embodiment are similar to those of the first embodiment, and are not redundantly described herein.

The first footer circuit 416 comprises a first switch M1 and a second switch M2. The first switch M1 is connected between the first control line CL1 and the ground terminal G. In addition, the first switch M1 is controlled by the first word line WL1. The second switch M2 is connected between the first control line CL1 and the ground terminal G. In addition, the second switch M2 is controlled by the second word line WL2.

The second footer circuit 426 comprises a third switch M3 and a fourth switch M4. The third switch M3 is connected between the second control line CL2 and the ground terminal G. In addition, the third switch M3 is controlled by the third word line WL3. The fourth switch M4 is connected between the second control line CL2 and the ground terminal G. In addition, the fourth switch M4 is controlled by the fourth word line WL4. In this embodiment, the switches M1˜M4 are all transistors. Moreover, the gate terminal is connected to the corresponding word line, the drain terminal is connected to the ground terminal G, and the source terminal is connected to the corresponding control line.

During a read cycle of the mask read-only memory 400, only one word line is a selected word line, and the other word lines are non-selected word lines. Hereinafter, the operations of the mask read-only memory 400 will be illustrated by using the fourth word line WL4 as the selected word line. Under this circumstance, the fourth switch M4 is closed, and the switches M1, M2 and M3 are opened. Consequently, the ground voltage of the ground terminal G is provided to the second control line CL2 through the fourth switch M4. Moreover, since the switches M1, M2 and M3 are opened, the voltages of the control lines CL1 and CL2 fail to be changed through the switches M1, M2 and M3.

In case that the second control line CL2 is too long, the voltages at both ends of the second control line CL2 may be somewhat different. The second footer circuit 426 of the second memory unit 400 is connected to the second control line CL2. Consequently, if the second control line CL2 has the low voltage level Lo, the voltages of all points of the second control line CL2 are substantially equal.

The function of the first footer circuit 416 of the first memory unit 410 is similar to that of the second footer circuit 426, and is not redundantly described herein.

In the above embodiments, the mask read-only memory comprises plural memory units, wherein each memory unit is defined by two word lines. However, those skilled in the art will readily observe that numerous modifications and alterations may be made while retaining the teachings of the invention. For example, in some other embodiments, each memory unit is defined by more than two word lines.

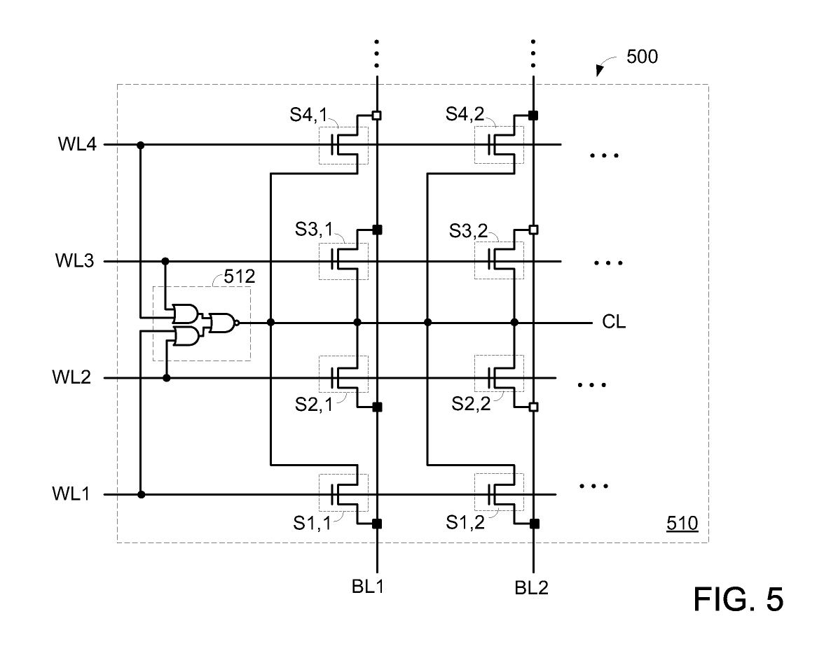

FIG. 5 is a schematic circuit block diagram illustrating a portion of a non-volatile memory according to a third embodiment of the present invention. In this embodiment, only one memory unit is shown. It is noted that plural memory units with the identical structure are combined as the non-volatile memory of this embodiment.

In this embodiment, the non-volatile memory is a mask read-only memory 500. The memory unit 510 of the mask read-only memory 500 is defined by four word lines WL1˜WL4. As shown in FIG. 5, the memory unit 510 comprises a logic circuit 512, a control line CL, a first word line WL1, a second word line WL2, a third word line WL3 and a fourth word line WL4, a first bit line BL1, a first bit line BL2, and eight cells S1,1˜S4,2 corresponding to these bit lines and these word lines. Moreover, each of the cells S1,1˜S4,2 comprises a transistor.

The first word line WL1 corresponds to the two cells S1,1˜S1,2. The gate terminal of the transistor of each of the cells S1,1˜S1,2 is connected to the first word line WL1. The source terminal of the transistor is connected to the control line CL. The drain terminal of the transistor is selectively connected to the corresponding bit line.

The second word line WL2 corresponds to the two cells S2,1˜S2,2. The gate terminal of the transistor of each of the cells S2,1˜S2,2 is connected to the second word line WL2. The source terminal of the transistor is connected to the control line CL. The drain terminal of the transistor is selectively connected to the corresponding bit line.

The third word line WL3 corresponds to the two cells S3,1˜S3,2. The gate terminal of the transistor of each of the cells S3,1˜S3,2 is connected to the third word line WL3. The source terminal of the transistor is connected to the control line CL. The drain terminal of the transistor is selectively connected to the corresponding bit line.

The fourth word line WL4 corresponds to the two cells S4,1˜S4,2. The gate terminal of the transistor of each of the cells S4,1˜S4,2 is connected to the fourth word line WL4. The source terminal of the transistor is connected to the control line CL. The drain terminal of the transistor is selectively connected to the corresponding bit line.

The logic circuit 512 of the memory unit 510 comprises two OR gates and a NOR gate. An output terminal of the logic circuit 512 is connected to the control line CL. In case that one of the word lines WL connected to the logic circuit 512 is a selected word line, the logic circuit 512 provides a low voltage level Lo to the control line CL. Whereas, in case that the all of the word lines WL connected to the logic circuit 512 are non-selected word lines, the logic circuit 512 provides a high voltage level Hi to the control line CL. It is note that the configuration of the logic circuit 512 may be varied according to the practical requirements. For example, in some other embodiments, the logic circuit 512 is implemented by a NOR gate with four input terminals.

Obviously, by controlling the voltage of the control line CL, the sub-threshold leakage current of the cell can be effectively suppressed.

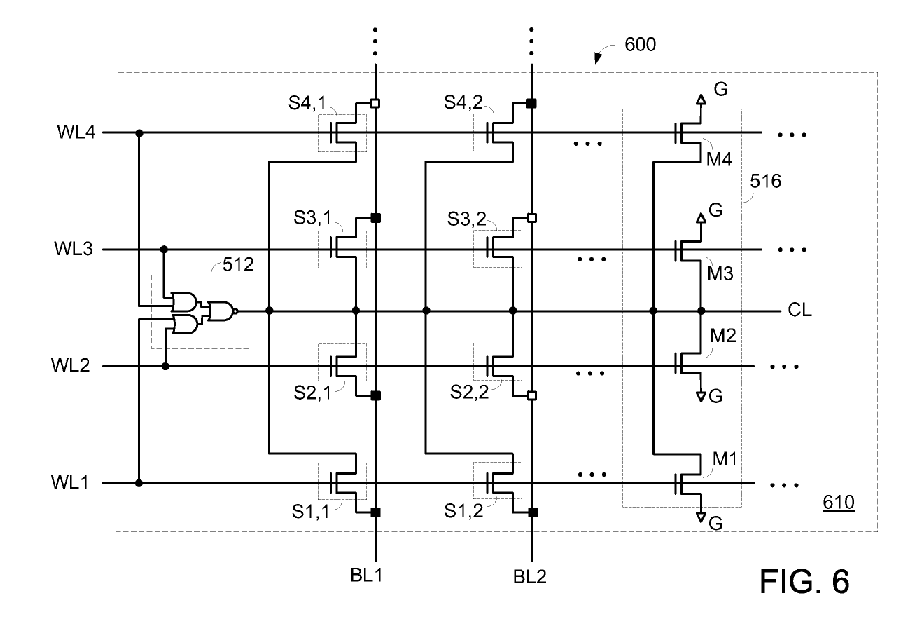

FIG. 6 is a schematic circuit block diagram illustrating a portion of a non-volatile memory according to a fourth embodiment of the present invention. In this embodiment, only one memory unit is shown. It is noted that plural memory units with the identical structure are combined as the non-volatile memory of this embodiment. In this embodiment, the non-volatile memory is a mask read-only memory 600. In comparison with the third embodiment, the memory unit 610 of the mask read-only memory 600 further comprises a footer circuit 516. Hereinafter, the configurations and the operating principles of the footer circuit 516 will be illustrated. The other parts of the mask read-only memory 600 of this embodiment are similar to those of the third embodiment, and are not redundantly described herein.

The footer circuit 516 comprises four switches M1˜M4. Each of the switches M1˜M4 is connected between the control line CL and the ground terminal G. Moreover, each of the switches M1˜M4 is controlled by the corresponding word line.

In case that one of the four word lines WL1 to WL4 is a selected word line, the ground voltage of the ground terminal G is provided to the control line CL through the corresponding switch. That is, since the footer circuit 516 is connected to the control line CL, the voltages of all points of the control line CL at the low voltage level Lo are substantially equal.

From the above descriptions, the present invention provides a non-volatile memory. The non-volatile memory comprises a logic circuit and a control line. The logic circuit has simple circuitry. The control line is used as a shared source line. By using the logic circuit to adjust the voltage of the control line, the sub-threshold leakage current of the cell can be largely reduced, and the possibility of causing erroneous judgment will be minimized.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A non-volatile memory comprising a first memory unit, the first memory unit comprising:
a first word line;
a second word line;
a first control line;
a first logic circuit having a first input terminal connected to the first word line, a second input terminal connected to the second word line, and an output terminal connected to the first control line, wherein if one of the first word line and the second word line is a selected word line, the output terminal of the first logic circuit provides a first voltage level to the first control line, wherein if the first word line and the second word line are non-selected word lines, the output terminal of the first logic circuit provides a second voltage level to the first control line;
a first bit line;
a first cell having a control terminal connected to the first word line, a first terminal connected to the first control line, and a second terminal selectively connected to the first bit line; and
a second cell having a control terminal connected to the second word line, a first terminal connected to the first control line, and a second terminal selectively connected to the first bit line.

2. The non-volatile memory as claimed in claim 1, wherein the first logic circuit is a NOR gate, wherein the NOR gate has a first input terminal connected to the first word line, a second input terminal connected to the second word line, and an output terminal connected to the first control line.

3. The non-volatile memory as claimed in claim 2, wherein the first voltage level is a low voltage level, and the second voltage level is a high voltage level.

4. The non-volatile memory as claimed in claim 1, wherein the first cell comprises a first transistor, wherein a gate terminal of the first transistor is the control terminal of the first cell, a source terminal of the first transistor is the first terminal of the first cell, and a drain terminal of the first transistor is the second terminal of the first cell, wherein the second cell comprises a second transistor, wherein a gate terminal of the second transistor is the control terminal of the second cell, a source terminal of the second transistor is the first terminal of the second cell, and a drain terminal of the second transistor is the second terminal of the second cell.

5. The non-volatile memory as claimed in claim 1, wherein if the second terminal of the first cell is connected to the first bit line, the first cell has a first storing state, wherein if the second terminal of the first cell is not connected to the first bit line, the first cell has a second storing state, wherein if the second terminal of the second cell is connected to the first bit line, the second cell has the first storing state, wherein if the second terminal of the second cell is not connected to the first bit line, the second cell has the second storing state.

6. The non-volatile memory as claimed in claim 1, wherein the first memory unit further comprises:
a second bit line;
a third cell having a control terminal connected to the first word line, a first terminal connected to the first control line, and a second terminal selectively connected to the second bit line; and
a fourth cell having a control terminal connected to the second word line, a first terminal connected to the first control line, and a second terminal selectively connected to the second bit line.

7. The non-volatile memory as claimed in claim 1, further comprising a second memory unit, wherein the second memory unit comprises:
a third word line;
a fourth word line;
a second control line;
a second logic circuit having a first input terminal connected to the third word line, a second input terminal connected to the fourth word line, and an output terminal connected to the second control line, wherein if one of the third word line and the fourth word line is the selected word line, the output terminal of the second logic circuit provides the first voltage level to the second control line, wherein if the third word line and the fourth word line are the non-selected word lines, the output terminal of the second logic circuit provides the second voltage level to the second control line;
the first bit line;
a fifth cell having a control terminal connected to the third word line, a first terminal connected to the second control line, and a second terminal selectively connected to the first bit line; and
a sixth cell having a control terminal connected to the fourth word line, a first terminal connected to the second control line, and a second terminal selectively connected to the first bit line.

8. The non-volatile memory as claimed in claim 1, wherein the first memory unit further comprises a first footer circuit, wherein the first footer circuit comprises:
a first switch having a control terminal connected to the first word line, a first terminal connected to the first control line, and a second terminal connected to a ground terminal; and
a second switch having a control terminal connected to the second word line, a first terminal connected to the first control line, and a second terminal connected to the ground terminal,
wherein if the first word line is the selected word line, a ground voltage is provided to the first control line through the first switch, wherein if the second word line is the selected word line, the ground voltage is provided to the first control line through the second switch.

9. The non-volatile memory as claimed in claim 8, wherein the first switch is a first transistor, wherein a gate terminal of the first transistor is the control terminal of the first switch, a source terminal of the first transistor is the first terminal of the first switch, and a drain terminal of the first transistor is the second terminal of the first switch, wherein the second switch is a second transistor, wherein a gate terminal of the second transistor is the control terminal of the second switch, a source terminal of the second transistor is the first terminal of the second switch, and a drain terminal of the second transistor is the second terminal of the second switch.

10. A non-volatile memory, comprising:
a bit line;
M word lines, wherein M is a positive integer larger than 2;
a control line;
a logic circuit having M input terminals connected to the M word lines, and having an output terminal connected to the control line, wherein if one of the M word lines is a selected word line, the output terminal of the logic circuit provides a first voltage level to the control line, wherein if the M word lines are non-selected word lines, the output terminal of the logic circuit provides a second voltage level to the control line; and
M cells,
wherein each of the M cells has a control terminal connected to one of the M word lines, a first terminal connected to the control line, and a second terminal selectively connected to the bit line.

11. The non-volatile memory as claimed in claim 10, wherein each of the M cells is a transistor, wherein a gate terminal of the transistor is the control terminal of the corresponding cell, a source terminal of the transistor is the first terminal of the corresponding cell, and a drain terminal of the transistor is the second terminal of the corresponding cell.

12. The non-volatile memory as claimed in claim 10, wherein the logic circuit is a NOR gate, wherein the NOR gate has M input terminals connected to the M word lines, respectively, wherein the NOR gate has an output terminal connected to the control line.

13. The non-volatile memory as claimed in claim 10, wherein if the second terminal of one of the M cells is connected to the bit line, the cell has a first storing state, wherein if the second terminal of one of the M cells is not connected to the bit line, the cell has a second storing state.

14. The non-volatile memory as claimed in claim 10, further comprising a footer circuit, wherein the footer circuit comprises M switches, wherein each of the M switches has a control terminal connected to one of the M word lines, a first terminal connected to the control line, and a second terminal connected to a ground terminal, wherein if one of the M word lines is the selected word line, a ground voltage is provided to the control line through the corresponding switch.
